(19) United States
(12) Patent Application Publication
(10) Pub. No.: US 2009/0021332 A1
(43) Pub. Date: Jan. 22, 2009

(54) ARRAY OF CAPACITORS SWITCHED BY MOS TRANSISTORS

(75) Inventors: Johannes Hubertus Antonius Brekelmans, Eindhoven (NL); Vincent Rambeau, Eindhoven (NL); Jan Van Sinderen, Cambes en Plaine (FR); Marc Godfriedus Marie Notten, Eindhoven (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/576,808

(22) PCT Filed: Oct. 5, 2005
(86) PCT No.: PCT/IB05/53271

§ 371 Date: Apr. 5, 2007

(30) Foreign Application Priority Data
Oct. 8, 2004 (EP) 04104945.3

(51) Int. Cl. H03J 5/24

(52) U.S. Cl. 334/55

(57) ABSTRACT

An integrated variable capacitance with low losses comprises an array (1) of switched capacitors (2-8). When using an array (1) of switched capacitors (2-8) to form a quasi continuously variable capacitor, a continuity of capacitance as function of the digital control signal to the array (1) leads to overall behavior of the series resistance of the array (1) as function of the capacitance that for some applications may be undesirable. Therefore a topology for a switched array (1) is proposed that allows to set series resistance relatively independent from capacitance. The array (1) may be fully or partially integrated in tunable LC filters, also in TV tuners.

The invention refers to an array of capacitors switched by MOS transistors.

Such an array of switched capacitors is known from WO 2001/076067. The array of capacitors replaces a varactor diode of an amplitude modulated radio receiver. An integrated radio frequency stage comprises the switched capacitors. A most suitable device to implement the switching function is a metal oxide semiconductor field effect transistor, MOSFET, MOST or MOS transistor for short. Acting as a switch, the MOS transistor comprises an On-Resistance and an Off-Capacitance.

The Off-Capacitance of the MOS transistors effects the total capacitance of the array. The series resistance of the array increases and decreases as function of the capacitance.

It is therefore an object of the invention to maintain monotonicity or at least a quasi monotonicity of capacitance as function of a digital control signal to the array.

It is a further object of the invention to maintain proportionality or at least a quasi proportionality of capacitance as function of the digital control signal to the array.

It is yet another further object of the invention to make an array where series resistance can be set relatively independent from capacitance, while still maintaining monotonicity or at least a quasi monotonicity of capacitance.

To achieve these objects, it is provided an array of capacitors, each having a capacitance, the array comprising MOS transistors for switching the array of capacitors, a geometric property of each of the MOS transistors being proportional to the capacitance of the capacitor to which the MOS transistor is coupled.

In the array each individual capacitor is switched with a MOS transistor. By applying a positive voltage to the gate of an NMOST, the NMOST is turned on. The simplified expression for the ON resistance between drain and source is

$${R}_{ON} = \frac{1}{{μ}_{n} {C}_{ox} \frac{W}{L} ( {V}_{GS} - {V}_{T} )} \qquad ( 1 )$$

where W and L are width and length of the MOST respectively, V_{T} is the threshold voltage, uₙ and Cₒₓ are IC technology dependent constants. Since the array capacitors can have relatively high Q, the On Resistance of various MOS transistors constitutes the major part of the total series resistance Rs of the array. To minimize Rs, the gate length L is given the minimum value and the gate-source voltage V_{GS} is chosen equal to supply voltage. This leaves the parameter W to set a certain value for the series resistance. When the MOST is in the Off state it forms a capacitor from drain to substrate (source) formed mainly by a reverse biased n+-Psub diode. The value of the capacitance, designated as Cdo, is proportional to the width W of the MOST

C_{do}∝W (2)

Cdo does not depend on L. It can be reduced by applying a reverse voltage, for example by pulling the drain terminal to the supply voltage when the MOST is switched off. Since one plate of capacitor Cdo is formed by the substrate there is a loss resistance Rsp associated with Cdo. An increase of W to reduce the series resistance will result in a proportional increase of Cdo. Given boundary conditions such as minimal L and VGS=Vsupply the product of Ron and Cdo forms a technology depending constant. The highest available DC voltage usually is the supply voltage. If the Gate Source voltage of MOST in the IC process can tolerate a voltage higher than the supply, it can be beneficial to use a DC-DC converter or second supply voltage to reduce On Resistance further.

The total capacitance Cvar of the capacitor array can be written as

$${C}_{VARj} = {\sum }_{i = 1}^{N} {C}_{i} , {b}_{ij} + {\sum }_{i = 1}^{N} \frac{{C}_{doi} \cdot {C}_{i}}{{C}_{doi} + {C}_{i}} \cdot ( 1 - {b}_{ij} )$$

$${C}_{VARj} = C \cdot {\sum }_{i = 1}^{N} {b}_{ij} \cdot {2}^{( i - 1 )} + {\sum }_{i = 1}^{N} \frac{{C}_{doi} \cdot {C}_{i}}{{C}_{doi} + {C}_{i}} \cdot ( 1 - {b}_{ij} )$$

where C is the unit capacitor value used for the Least Significant Bit, LSB for short, and bᵢⱼ is defined with bⱼ=(b₁ⱼ,b₁ⱼ, . . . , b_{Nj}) where bj is the binary translation of j.

$$j = {\sum }_{i = 1}^{N} {b}_{ij} \cdot {2}^{( i - 1 )} ( 0 < j < {2}^{N} - 1 )$$

$${C}_{VAR j} = C \cdot j + {\sum }_{i = 1}^{N} \frac{{C}_{doi} \cdot {C}_{i}}{{C}_{doi} + {C}_{i}} \cdot ( 1 - {b}_{ij} )$$

For monotonicity of capacitance curve as a function of the binary word ‘j’, the requirement is found that the series circuit of Cdoi and Ci follows a binary sequence

$${\sum }_{i = 1}^{N} \frac{{C}_{doi} \cdot {C}_{i}}{{C}_{doi} + {C}_{i}} {b}_{ij} ∝ j ⇒ \frac{{C}_{doi} \cdot {C}_{i}}{{C}_{doi} + {C}_{i}} ∝ {2}^{( i - 1 )}$$

Defining a constant k as

$$k = \frac{C \cdot {2}^{i - 1}}{{C}_{doi}} \qquad ( 4 )$$

then C_{doi}=k·C·2⁽ⁱ⁻¹⁾ and

$${C}_{VAR j} = C \cdot j \cdot \frac{1}{1 + k} + \underbrace{C \cdot ( {2}^{N} - 1 ) \cdot \frac{k}{1 + k}}_{{C}_{min}} ( 0 < j < {2}^{N} - 1 ) \qquad ( 5 )$$

A first solution is given, if the series circuit of Cdoi and Ci together are a constant fraction of Ci, then the capacitance characteristic will be continuous and linear. The continuity is of importance for the tuning procedure. The continuity condition is fulfilled when Cdoi is made to be a fraction of Ci in accordance with equation (4). As indicated by equation (2) capacitance Cdoi will be proportional with the width Wi of the MOSTi. So continuity of capacitance characteristic is met when

Wᵢ∝C·2⁽ⁱ⁻¹⁾ (6)

The width of the MOS transistors, and thus their Off-state capacitance, is proportional to capacitances of the array capacitors. The consequence of having to select Wi proportional to Ci is that the series resistance will decrease towards higher capacitance values. The capacitor characteristic tends to become constant Q rather than constant Rs When each MOST is given the same width and hence will have the same On Resistance,discontinuities appear in both the capacitance and series resistance characteristic.

Calculating the capacitance ratio available from the array

$$\begin{matrix}{C}_{MAX} = C \cdot ( {2}^{N} - 1 ) \cdot \frac{1}{1 + k} + C \cdot ( {2}^{N} - 1 ) \cdot \frac{k}{1 + k} = C \cdot ( {2}^{N} - 1 ) & ( 7 ) \\ {C}_{MIN} = C \cdot 0 \cdot \frac{1}{1 + k} + C \cdot ( {2}^{N} - 1 ) \cdot \frac{1}{1 + k} = C \cdot ( {2}^{N} - 1 ) \cdot \frac{k}{1 + k} & ( 8 )\end{matrix}$$

This gives the maximum available capacitance ratio from the array

$$η = \frac{{C}_{MAX}}{{C}_{MIN}} = \frac{1}{k} + 1$$

which can also be written as

$$η = \frac{{C}_{MAX}}{{C}_{MIN}} = \frac{{C}_{doi}}{{C}_{i}} + 1$$

C_{MIN} is determined by the sum of parasitic capacitances contributed by the MOST switches, leaving out of consideration the parasitic capacitance contributed by the array capacitors, interconnect, bonding, package and application. The most significant bit, MSB for short, contributes half of it, the MSB-1 about 25%, et cetera. For a 7 bit array the least significant bit, LSB for short, contribution to C_{MIN} is 1/128. If we increase the number of bits N by 1 we need to half the unit capacitor C to maintain the same Cₘₐₓ and Cₘᵢₙ, Cdoi will increase by only 1/256. Therefore, changing the number of bits of the array has negligible effect on the capacitance ratio or on the series resistance.

Capacitance monotonicity dictates the size of each MOST in the array. When used as variable capacitor in a LC tunable filter the required MOST size per bit leads to an undesired behavior of series resistance as function of capacitance. Therefore the invention further proposes a topology for a switch array that allows to set series resistance relatively independent from capacitance, while still maintaining monotonicity. To this end a number of MOST switches used in the less significant bits are increased in size. Doing so will reduce series resistance at low capacitance values. To compensate for too high capacitance contribution of the MOST's in the off-state, dummy branches are added that are removed in the off-state.

If one neglects the parasitic capacity of the MOS switches, the capacity of a branch comprising a switch and a capacitor is Cᵢ=2ⁱ⁻¹*ΔC, wherein ΔC is a step size capacity and i=1, 2, . . . , max. In reality, there is a parasitic capacity of the switches, which affects the dependence between the capacitance of the array as a function of tuning voltage. If the parasitic capacity is considered then jumps are observed in the plot of the capacitance as a function of tuning voltage.

To prevent these jumps, the capacitance of the switches is increased as shown in the following relation, wherein Cₚᵢ is the parasitic capacitance of the switch in OFF state.

$${C}_{i} = {2}^{i - 1} \cdot Δ C + \frac{{C}_{i} \cdot {Cp}_{i}}{{C}_{i} + {Cp}_{i}}$$

This gives

$${C}_{i} = \frac{1}{4} \cdot ( {2}^{i} \cdot Δ C + {2}^{\frac{i}{2}} \cdot \sqrt{Δ C} \cdot \sqrt{8 \cdot {Cp}_{i} + {2}^{i} \cdot Δ C} )$$

Unfortunately, the equivalent series resistance of the capacitor array depends on the tuning voltage, having a minimum value and a maximum value. For constant bandwidth and voltage standing wave ratio, VSWR for short, as function of tuning, the equivalent series resistance should be constant. To lower the ratio between the maximum and minimum value, the switch sizes can be optimised.

Further improvement can be obtained by splitting each switch in parallel switches. By this method, when the switches are selectively deactivated i.e. they are in an OFF state, the equivalent resistance increases and reciprocally, when the switches are selectively activated i.e. they are in an ON state the equivalent resistance decreases.

Still, process spread can cause jumps in the capacitance-tuning curve and influence the tuning range. When the capacitors in the array are smaller and/or switch parasitic larger, gaps will occur and not all capacitors values can be tuned to. If the parasitic capacitance increases, then the minimum tuned capacitor also increases. If the capacitors in the array are smaller, then the maximum tuned capacitor is reduced proportionally. The smallest tuned capacitor value is less affected. To prevent gaps in the tuning characteristic i.e. the dependency between the tuned capacity and the tuning voltage, overlap should be considered by calculating the capacitance of the capacitors in the array in the worst case i.e. when the parasitic capacitance has a maximum value Cpmax. After this, the value of the capacitors in the array should be multiplied by the ratio nominal capacitance/minimal capacitance array capacitor value, which is the worst case. Tuning range should be sufficient for the worst case situation.

The array itself, together with other electronic components to set the series resistance, are integrated on a single chip.

Of available capacitor types in today state-of-the-art integrated circuit processes, IC processes for short, Metal-Insulator-Metal capacitors, MIM capacitors for short, offer the highest quality factor. A binary weighted array is the most efficient implementation for generating large capacitance ratio with minimal number of components. The required resolution of the capacitance array depends on bandwidth and tuning range of the radio frequency filters, RF filters for short, to be realized. To replace a discrete varactor diode in traditional tuners, an array with around 7 or 8 bits is needed.

The array may be used to create fully or partially integrated tunable LC filters, for example for use in TV tuners.

The invention, together with further objects and advantages thereof, may best be understood by reference to the following description taken in connection with the accompanying drawings.

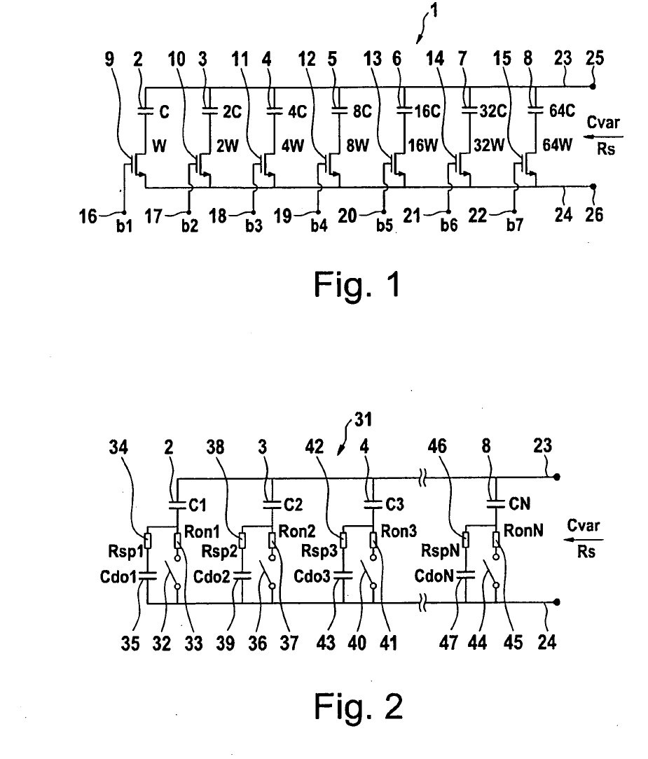

FIG. 1 is an embodiment of a 7 bit binary weighted array of capacitors switched by MOS transistors,

FIG. 2 is a schematic diagram of the equivalent circuit for the array as shown in FIG. 1,

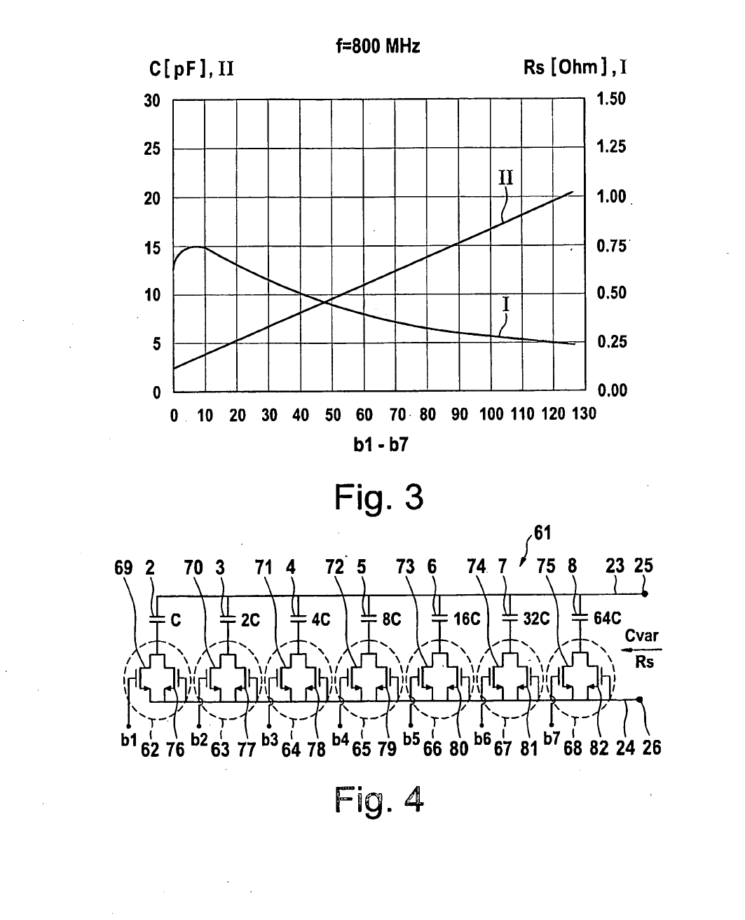

FIG. 3 is a graph I showing a series resistance of the array shown in FIGS. 1 and 2 versus an input word. Graph II is the capacity of the array shown in FIGS. 1 and 2 versus the input word,

FIG. 4 is an embodiment of a 7 bit binary weighted capacitor array with MOST switches split in active and passive MOST,

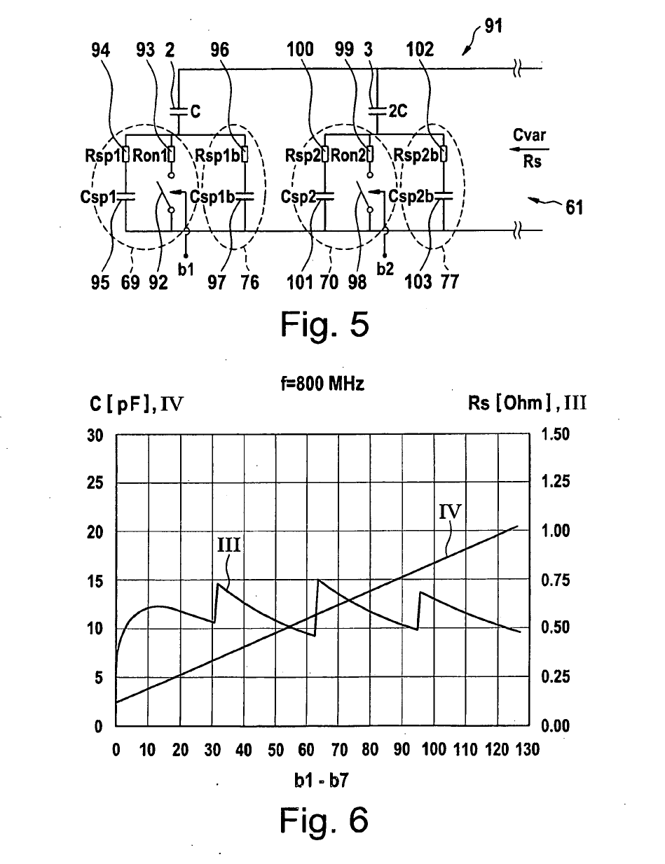

FIG. 5 is a schematic diagram of an equivalent circuit of FIG. 4,

FIG. 6 is a graph II showing a series resistance of the array shown in FIGS. 4 and 5 versus an input word. Graph FV is the capacity of the array shown in FIGS. 4 and 5 versus the input word,

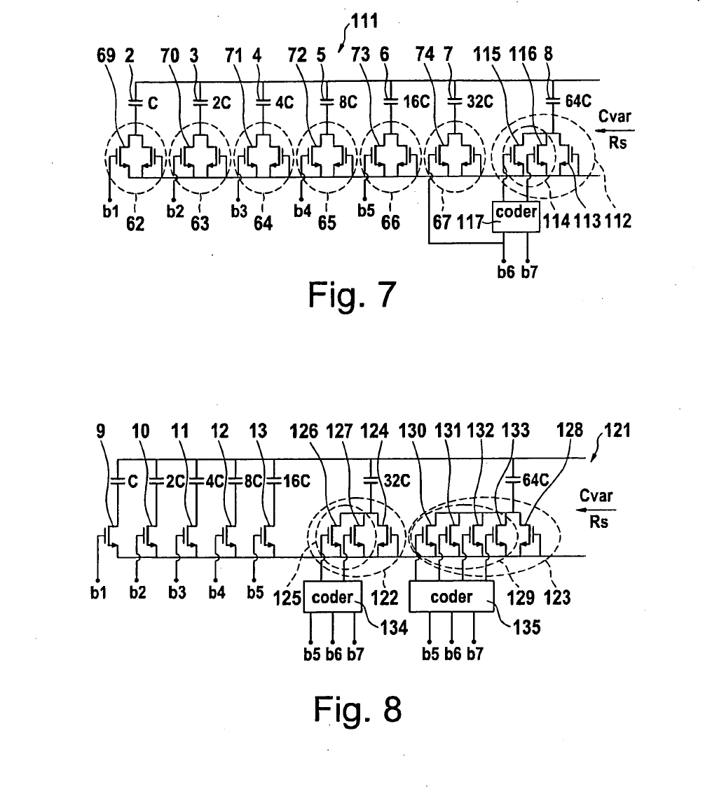

FIG. 7 is an embodiment of a 7 bit binary weighted capacitor array with active and passive MOST switches, where the active part of bit 7 is split in two MOST,

FIG. 8 is an embodiment of a 7 bit binary weighted capacitor array with multiple active and passive MOST switches and active parts of bit 6 and 7 are split in two and four MOST's respectively,

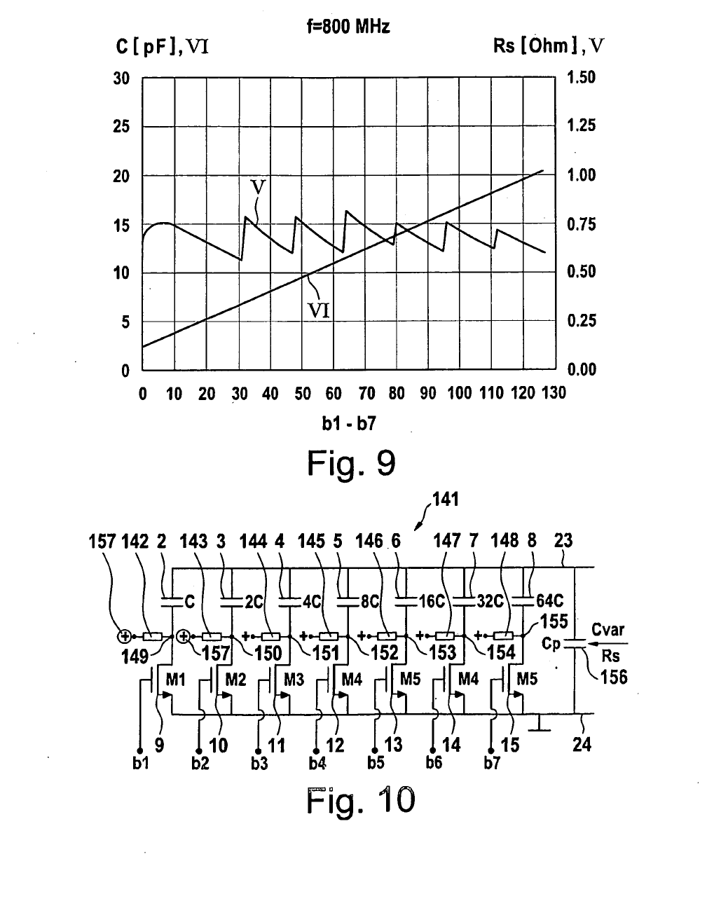

FIG. 9 is a graph V showing a series resistance of the array shown in FIG. 8 versus an input word. Graph VI is the capacity of the array shown in FIGS. 7 and 8 versus the input word,

FIG. 10 is an embodiment of a 7 bit binary weighted switched capacitor array with individual drain Pull-up resistors,

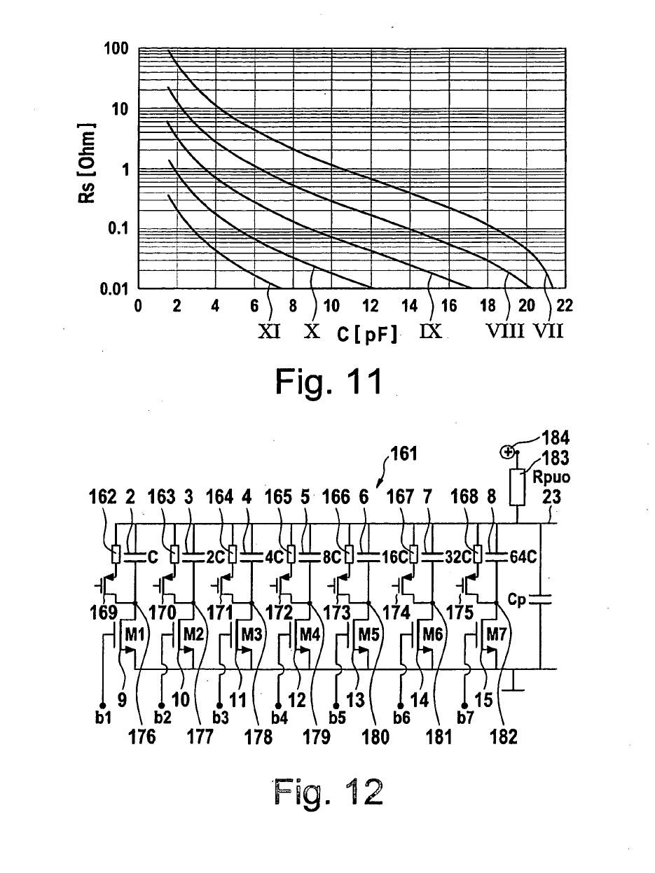

FIG. 11 is a graph VII showing a contribution to series resistor Rs by the individual Pull-up resistors versus a capacitance at 50 MHz. Graphs VIII, IX, X, XI show a contribution to series resistor Rs by the individual Pull-up resistors versus a capacitance at 100, 200, 400 and 500 MHz,

FIG. 12 is an embodiment of a 7 bit binary weighted switched capacitor array with individual Pull-up resistors connected to the signal line and switched on and off with a small PMOST,

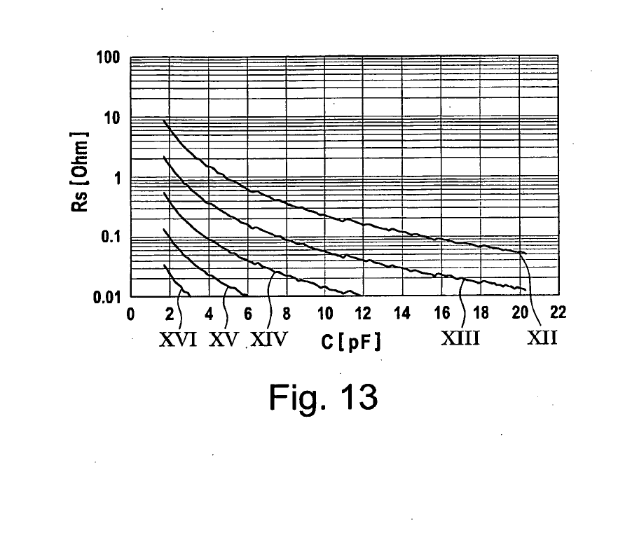

FIG. 13 is a graph XII showing a contribution to series resistor Rs by the individual switched Pull-up resistors versus a capacitance at 50 MHz. Graphs XIII, XIV, XV, XVI show a contribution to series resistor Rs by switched Pull-up resistors versus a capacitance at 100, 200, 400 and 500 MHz,

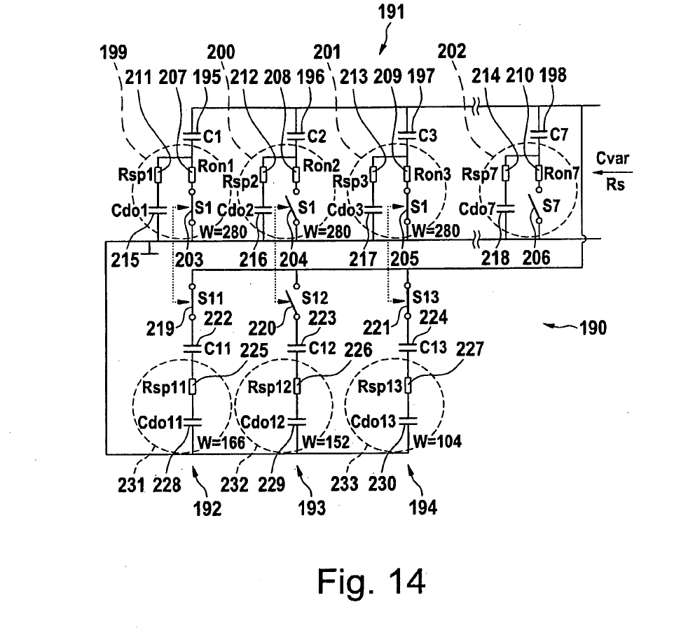

FIG. 14 is a schematic diagram of an equivalent circuit showing dummy branches added to the three least significant bits of a capacitance array,

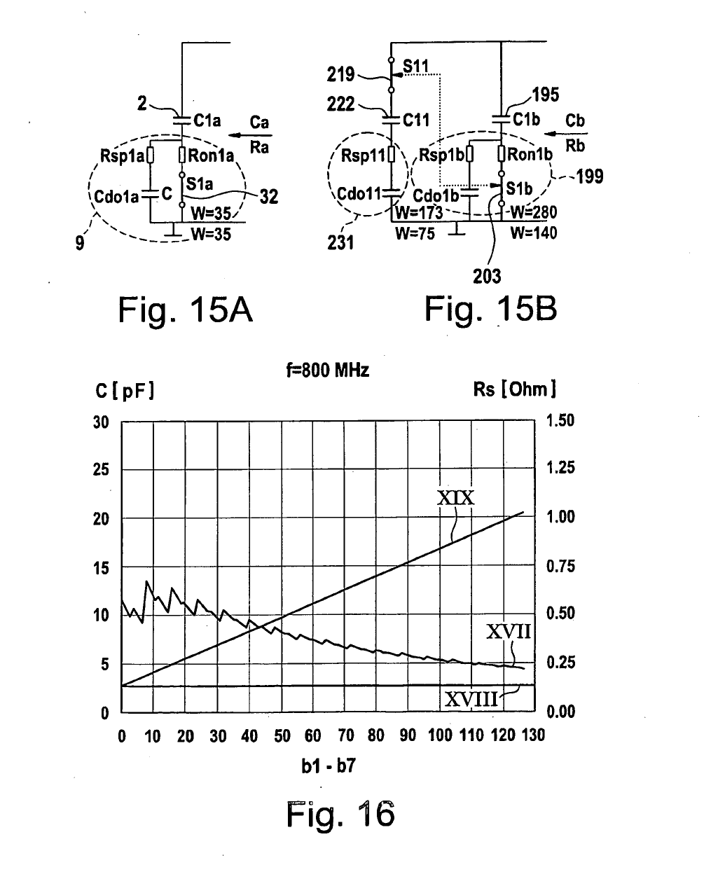

FIG. 15A shows a part of the circuit shown in FIG. 2 for explaining operation,

FIG. 15B shows a part of the circuit shown in FIG. 14 for explaining operation,

FIG. 16 is a graph XVII showing a linearized series resistance versus an input word resulting from circuit FIG. 14. Graphs XVIU and XIX show a first derivative of capacitance versus input word dC/dW as well as capacitance versus the input word,

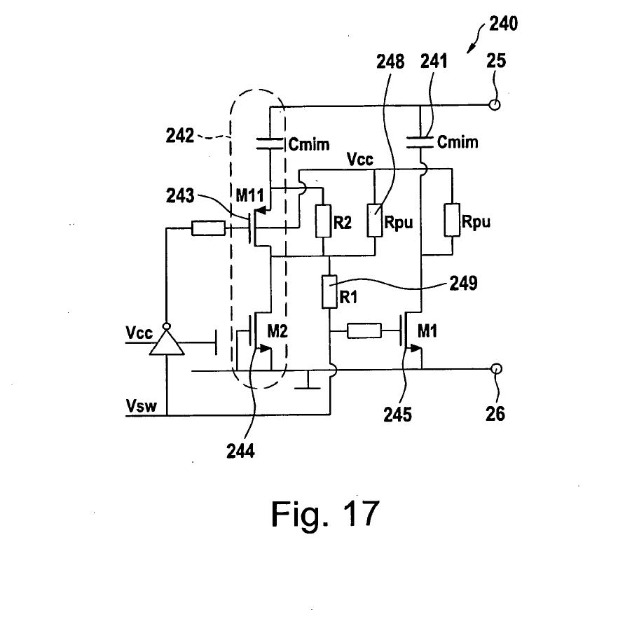

FIG. 17 is an embodiment of one array component with one switched capacitor and one dummy branch,

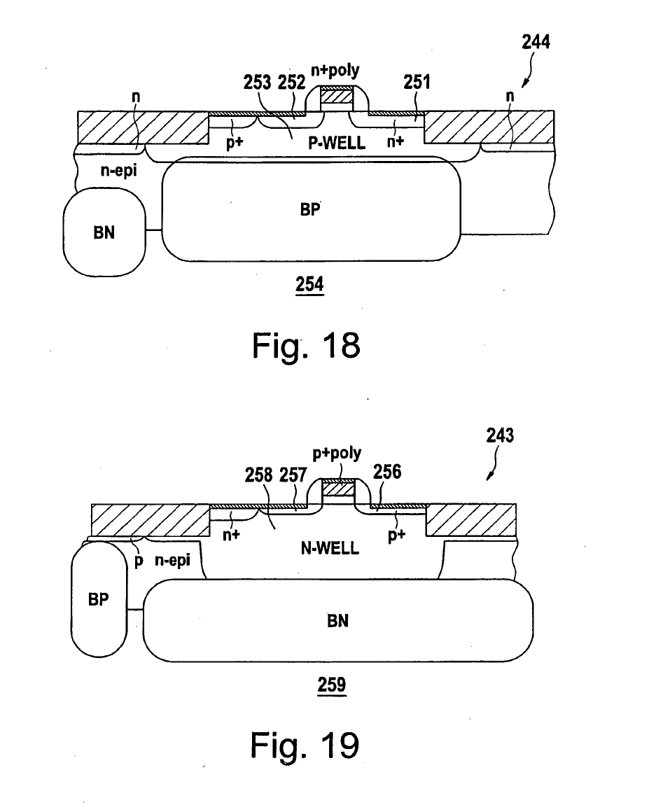

FIG. 18 is a cross section of a NMOS transistor,

FIG. 19 is a cross section of a PMOS transistor,

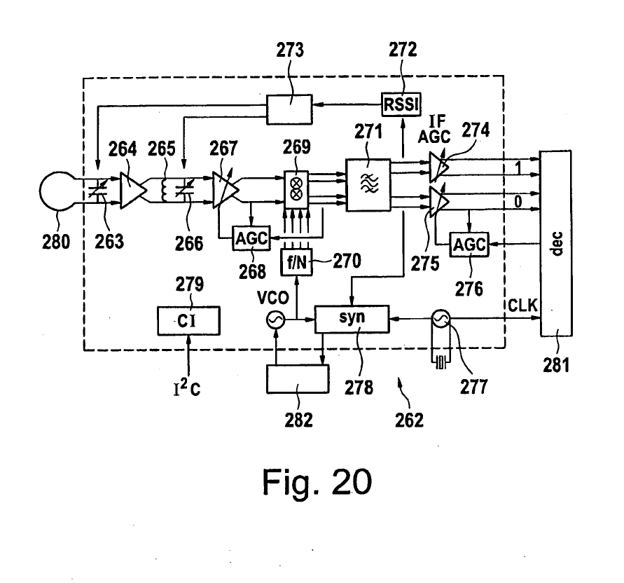

FIG. 20 is an embodiment of a receiver using a capacitance array,

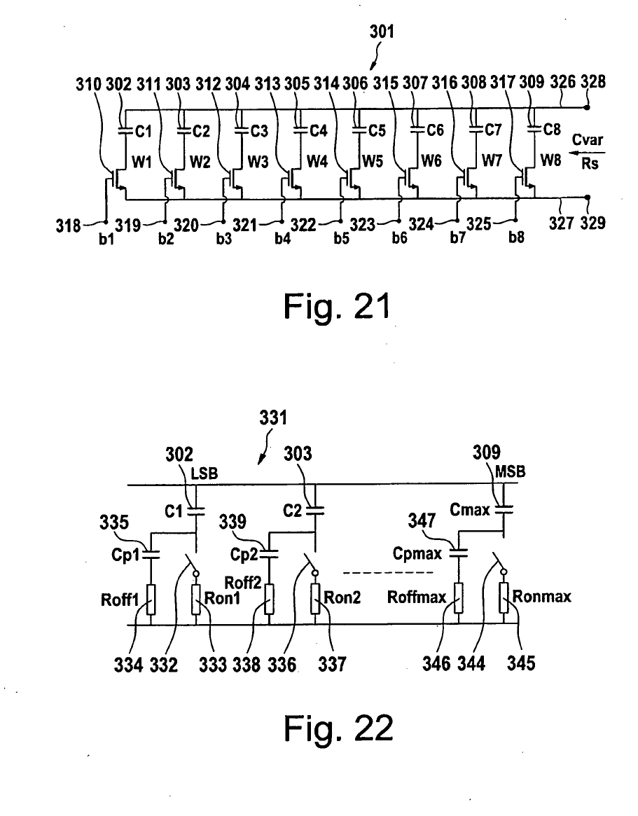

FIG. 21 is an embodiment of an 8 bit array of capacitors switched by MOS transistors, wherein a value of one array capacitor is a composition of a weighted basic value increased by an additional value,

FIG. 22 is a schematic diagram of the equivalent circuit for the array as shown in FIG. 21,

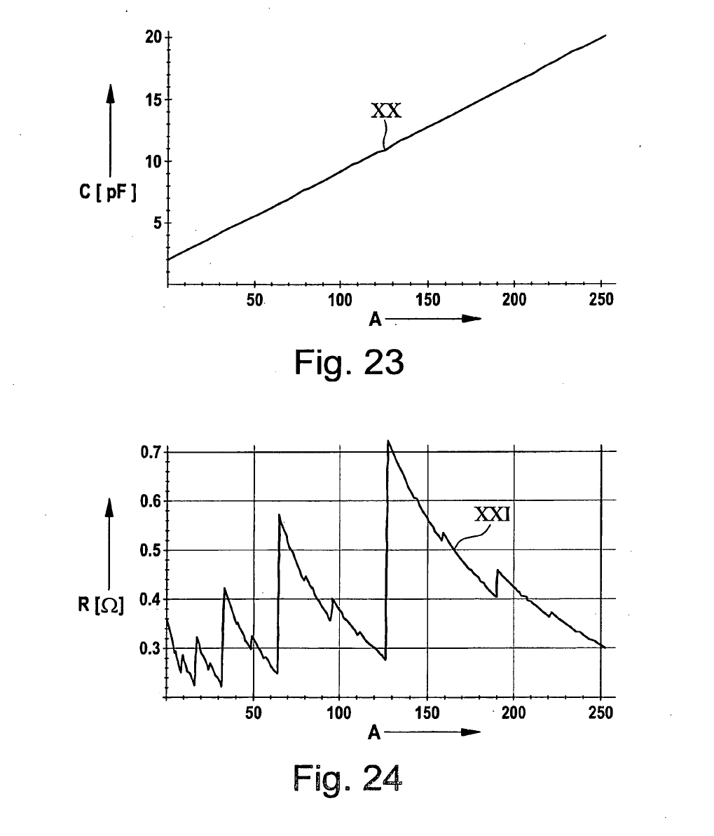

FIG. 23 is a graph XX showing a capacitance quasi proportional versus a tuning range,

FIG. 24 is a graph XXI showing an equivalent series resistance versus the tuning range,

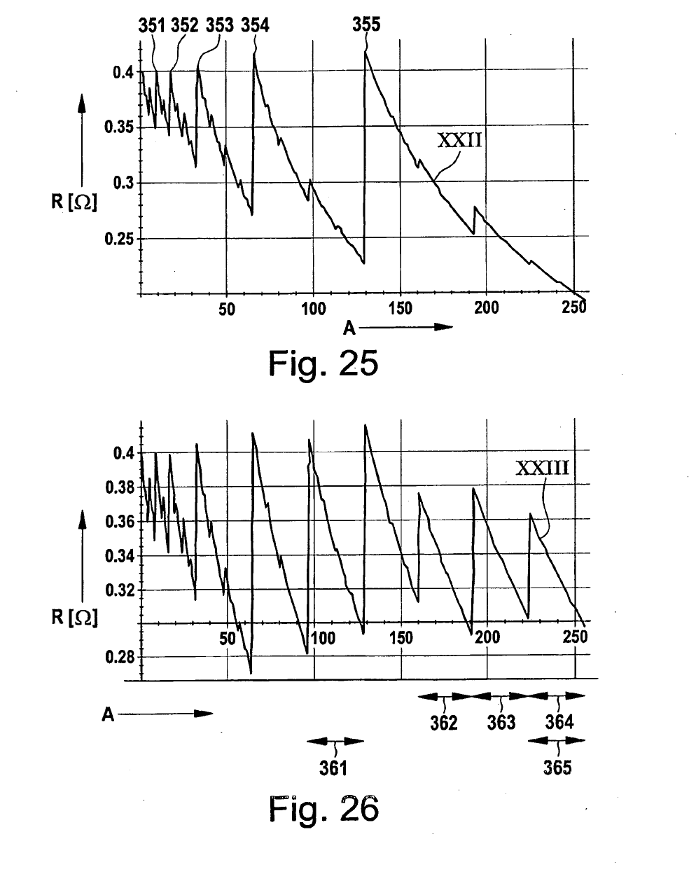

FIG. 25 is a graph XXII showing an optimised equivalent series resistance versus the tuning range,

FIG. 26 is a graph XXIII showing an equivalent series resistance optimised by splitting switches versus the tuning range and

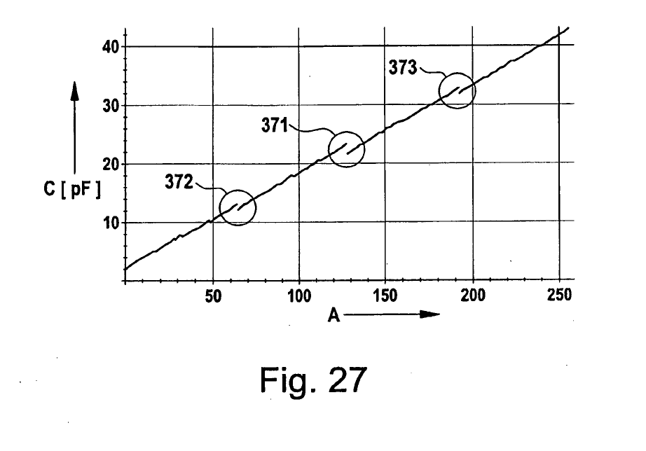

FIG. 27 is a graph XXIV showing a capacitance with overlaps versus the tuning range.

In the various Figures, the same reference numbers identifies the same or similar elements shown.

FIG. 1 shows an embodiment of a 7 bit binary weighted array I of capacitors 2-8 switched by MOS transistors 9-15 having Off state output capacitances proportional to the values of the capacitors 2-8 switched by the transistors 9-15. The MOS transistors 9-15 receive their control signal via inputs 16-22. The capacitance of array capacitor 3 is twice as large as the capacitance of array capacitor 2. The capacitance of array capacitor 4 is twice as large as the capacitance of array capacitor 3 and so on. The array capacitors 2-8 are connected in parallel to output terminal 25. The transistors 9-15 are in series with the capacitors 2-8. The capacitor 2 is in series with transistor 9. The capacitor 3 is in series with transistor 10 and so on. The capacitors 2-8 are connected with a signal line 23 and the transistors 9-15 to an output line 24 which can be ground. The output line 24 is also designated as second signal line. Inputs 16-22 receive binary coded control signals b1-b7 forming an array input word. The input word controls the array MOS transistors 9-15. A width W of transistor 10 is twice as large as width W of transistor 9. A width W of transistor 11 is twice as large as width W of transistor 10. The array 1, between signal terminals 25 and 26, replaces a varactor diode with capacitance Cvar and a series resistance Rs.

FIG. 2 shows a schematic diagram of the equivalent circuit 31 for the array 1. Transistor 9 is replaced by a circuit comprising a switch 32, a resistor 33 representing the MOST On-Resistance Ron1, a capacitor 35 in series with resistor 34 representing the parasitic Off-Capacitance Cdo1 and parasitic series resistance Rsp1 respectively. Like wise, Transistor 10 is replaced by a circuit comprising a switch 36, a resistor 37 representing the MOST On-Resistance Ron2, a capacitor 39 in series with resistor 38 representing the parasitic Off-Capacitance Cdo2 and parasitic series resistance Rsp2 respectively. Transistor 15 is replaced by a circuit comprising a switch 44, a resistor 45 representing the MOST On-Resistance RonN, a capacitor 47 in series with resistor 46 representing the parasitic Off-Capacitance CdoN and parasitic series resistance RspN respectively:

The following table shows for each bit the width W of the MOS transistors, the MOST Off-state capacitance Cdo of capacitors 35, 39, 43 and 47, the MOST on resistance Ron of resistors 33, 37, 41 and 45, the resistance Rsp of bulk resistors 34, 38, 42 and 44 and the capacitance Cmin of capacitors 2-8.

| W | Cmim | Ron | Cdo | Rsp |
|---|---|---|---|---|
| (um) | (pF) | (Ohm) | (pF) | (Ohm) |
| 2240.0 | 10.240 | 0.469 | 1.515 | 1.320 |
| 1120.0 | 5.120 | 0.938 | 0.757 | 2.641 |
| 560.0 | 2.560 | 1.875 | 0.379 | 5.282 |
| 280.0 | 1.280 | 3.750 | 0.189 | 10.563 |
| 140.0 | 0.640 | 7.500 | 0.095 | 21.127 |
| 70.0 | 0.320 | 15.000 | 0.047 | 42.254 |
| 35.0 | 0.160 | 30.000 | 0.024 | 84.507 |

FIG. 3 is a graph I showing the series resistance of the array I shown in FIGS. 1 and 2 versus the input word b1-b7. Graph II is the capacitance of the array 1 shown in FIGS. 1 and 2 versus the input word b1-b7. Only when the series circuit of Cdoi and Ci together are a constant fraction of Ci, the capacitance characteristic will be continuous and linear. The consequence of having to select Wi proportional to Ci is that the series resistance will decrease towards higher capacitance values.

FIG. 4 shows an embodiment of a capacitor array 61 with switches 62-68, each switch is split in an active MOS transistor 69-75 and a further passive MOS transistor 76-82. One MOS transistor 69-75 and one further MOS transistor 76-82 are connected in parallel at the drain and together connected in series with array capacitor 2-8. Switch 62 comprises an active MOS transistor 69 and a passive MOS transistor 76, switch 63 comprises an active MOS transistor 70 and a passive MOS transistor 77 and so on. With this topology more independent control over series resistance and capacitance is gained. The passive part 76-82 is present to obtain the required Cdo capacitance needed for continuity of capacitance as function of the input word b1-b7. The passive MOST's are always OFF so the gate terminals can be permanently connected to signal line 24, acting as the reference terminal. The active part 69-75 comprises a fraction of the total MOST chosen such that overall a series resistance is obtained that is in accordance with the desired characteristic.

FIG. 5 shows a schematic diagram of the equivalent circuit 91 for the array 61 and is drawn with simplified equivalent R and C model for the MOS transistors, showing only the 2 least significant bits. The components associated with the passive MOST's are indicated with subscript “b”. Transistor 69 is replaced by switch 92, resistor 93 with On-Resistance Ron1, resistor 94 with parasitic series resistance Rsp1 and capacitor 95 with parasitic series capacitance Csp1. Passive MOS transistor 76 is replaced by resistor 96 with parasitic series resistance Rsp1b and capacitor 97 with parasitic series capacitance Csp1b. Transistor 70 is replaced by switch 98, resistor 99 with On-Resistance Ron2, resistor 100 with parasitic series resistance Rsp2 and capacitor 101 with parasitic series capacitance Csp2. Passive MOS transistor 77 is replaced by resistor 102 with parasitic series resistance Rsp2b and capacitor 103 with parasitic series capacitance Csp2b.

FIG. 6 depicts a graph III showing the series resistance of the array 61 shown in FIGS. 4 and 5 versus the input word b1-b7. Graph IV is the capacity of the array 61 shown in FIGS. 4 and 5 versus the input word b1-b7. Graph III shows the bit 7 being active in the word range 64-127. The bit 6 branch is active in the range 32-63 and 96-127. Closer examination shows that the equalizing effect of the active/passive split of bit 6 is much more pronounced at the input word transition 31-32 but hardly has effect at the input word transition 95-96. Reason is that at latter transition point capacitance of b7 is switched on, masking effect of b6. The array capacitance at 95 is 15.9 pF while at 31 it is only 6.94 pF.

FIG. 7 is an embodiment of a capacitor array 111 with switches 62-67 and 112. Switch 112 comprises a passive MOST 113 and an active part 114 comprising two MOST 115 and 116. A coder 117 receives bits 6 and 7 of the input word b1-b7 and controls active MOST 74, 115 and 116. Therefore the control of series resistance is further refined by multiple active MOST 115 and 116 per bit. The active part 114 is split in two. An independent correction of series resistance at the transition points 31-32 and 95-96 is realized by switching off one MOST either 115 or 116 of part 114 from 96 onwards.

FIG. 8 is an embodiment of a capacitor array 121 with switches 9-13, 122 and 123. Switch 122 comprises a passive MOST 124 and an active part 125 comprising two MOST 126 and 127. Switch 123 comprises a passive MOST 128 and an active part 129 comprising four MOSTs 130-133. Two coders 134 and 135 receive bits b5, b6 and b7 of the input word b1-b7 and control active MOST 126, 127 and 130-133. Therefore the control of the series resistance is further refined by multiple active MOST 126, 127 and 130-133 per bit. The active part 125 is split in two and the active part 129 is split in four parallel MOSTs 126, 127 and 130-133.

FIG. 9 shows a result of a 7 bit capacitor array optimized using topology according FIG. 8 and is a graph V showing series resistance of the array 121 shown in FIG. 8 versus input word b1-b7. Graph VI is the capacity of the array shown in FIG. 8 versus the input word. An independent correction of series resistance at the transition points 31-32, 47-48, 63-64, 79-80, 95-96 and 121-122 is realized by choosing one or several active MOST 126, 127, 130-132 or 133 of part 125 and 129 from 31 onwards.

FIG. 10 shows an embodiment of a 7 bit binary weighted array 141 of capacitors 2-8 switched by MOS transistors 9-15. Individual Pull-up resistors 142-148 are connected to taps 149-155 between capacitors 2-8 and transistors 9-15. The Pull-up-resistor 142 is connected to tap 149 between capacitor 2 and transistor 9. The Pull-up-resistor 143 is connected to tap 150 between capacitor 3 and transistor 10 and so on. A capacitor 156 with parallel capacitance Cp is fixed between signal lines 23 and 24 to account for stray capacitance. Pull-up-resistor 142 has 6400 kOhm, Pull-up-resistor 143 has 3200 kOhm, Pull-up-resistor 144 has 1600 kOhm and so on, Pull-up-resistor 148 has 100 kOhm. Individual Pull-up-resistors 142-148 contribute to capacitor series resistance Rs whenever the MOS transistors are in the Off state. The Pull-up-resistors 142-148 are connected to a positive supply 157.

FIG. 11 is a graph VII showing a contribution to series resistor Rs versus the array capacitance by the Pull-up-resistors 142-148 at 50 MHz. Graphs VIII, IX, X, XI show a contribution to series resistor Rs by the Pull-up-resistors 412-148 at 100, 200, 400 and 500 MHz.

FIG. 12 shows an embodiment of a 7 bit binary weighted array 161 of capacitors 2-8 switched by MOS transistors 9-15. Pull-up-resistors 162-168 are connected to the signal line 23 and via additional MOS transistors 169-175 to taps 176-182. Individual Pull-up is taken from signal line 23 and switched with small PMOST 169-175. The signal line 23 is connected via resistor 183 with resistance Rpuo to a positive supply 184. MOS transistor 169 is switched off when MOS transistor 9 is switched on. Reversely, MOS transistor 169 is switched on when MOS transistor 9 is switched off. And so on. Drain pull up resistors of each branch are switched on and off in conjunction with the switching of main MOST. When NMOST is on the PMOST is off and vice versa.

FIG. 13 shows a graph XII showing a contribution to the series resistor Rs by the individually switched Pull-up resistors versus the array capacitance at 50 MHz. Graphs XIII, XIV, XV, XVI show a contribution to the series resistor Rs by the switched Pull-up resistors versus a capacitance at 100, 200, 400 and 500 MHz.

FIG. 14 shows an equivalent circuit 190 with a 7 bit binary weighted switched capacitance array 191 and with dummy branches 192-194 added to three Least Significant Bits b1-b3, LSB b1-b3 for short. The array 191 comprises seven capacitors in series 195-198 with seven MOST 199-202, only the ones of interest are shown. Each MOST 199-202 comprises one array MOST switch 203-206, one resistor 207-210 with On-resistance Ron1, Ron2, Ron3 and Ron7, one resistor 211-214 with parasitic series resistance Rsp1, Rsp2, Rsp3 and Rsp7 and one capacitor 215-218 with a capacitance Cdo1, Cdo2, Cdo3 and Cdo7. The width W of capacitors 215-217 is 280 μm. Each branch 192-194 comprises one dummy MOST switch 219-221, one capacitor 222-224 with a capacitance C11, C12 and C13, one resistor 225-227 with a resistance Rsp11, Rsp12 and Rsp13 and one capacitor 228-230 with a capacitance Cdo11, Cdo12 and Cdo 13. Cdo11 to Cdo13 are formed by dummy MOST transistors 231-233 permanently in off state. The capacitors 195-197 and 222-224 all have the same value, C11=C12=C13=C1=C2=C3. Relevant values of members 195-230 are placed in the following table, wherein Wdes is the width of a binary weighted MOST, as shown in previous Figures, Wact is the width of the MOST 199, 200, 201 and 202 as shown in this Figure, Cmin is the capacity of switched Capacitors 195, 196, 197 and 198, Ron is the On Resistance of resistors 207, 208, 209 and 210, Cdo is the off capacitance of capacitors 215, 216, 217 and 218, Ceff is the series capacitance of capacitors 195 and 215, 196 and 216, 197 and 217, 198 and 218, Wdum is the width of the dummy MOSTs 231-233, Cdum is the Capacity of the dummy MOSTs 231-233, Cdumeff is the series capacitance, contributed by capacitors 222 and 228, 223 and 229, 224 and 230 in the dummy branches 192-194.

| | Wdes | Wact | Cmin | Ron | Cdo | Ceff | Wdum | Cdum | Cdumeff |
|---|---|---|---|---|---|---|---|---|---|
| Bit | (μm) | (μm) | (pF) | (ohm) | (pF) | (pF) | (μm) | (pF) | (pF) |
| 7 | 2240.0 | 2240.0 | 10.240 | 0.469 | 1.5147 | 1.3195 | 0.0 | 0.0000 | 0.0000 |
| 6 | 1120.0 | 1120.0 | 5.120 | 0.938 | 0.7573 | 0.6597 | 0.0 | 0.0000 | 0.0000 |
| 5 | 560.0 | 560.0 | 2.560 | 1.875 | 0.3787 | 0.3299 | 0.0 | 0.0000 | 0.0000 |
| 4 | 280.0 | 280.0 | 1.280 | 3.750 | 0.1893 | 0.1649 | 0.0 | 0.0000 | 0.0000 |
| 3 | 140.0 | 280.0 | 0.640 | 3.750 | 0.1893 | 0.1461 | 103.9 | 0.0702 | 0.0633 |
| 2 | 70.0 | 280.0 | 0.320 | 3.750 | 0.1893 | 0.1190 | 152.3 | 0.1030 | 0.0779 |
| 1 | 35.0 | 280.0 | 0.160 | 3.750 | 0.1893 | 0.0867 | 165.5 | 0.1119 | 0.0658 |

In order to reduce the series resistance of the array 191 in the lower capacitance range, created with the less significant bits b1-b3, the size of the MOS switches 199-201 of the LSB bits is increased. This causes a disturbed capacitance ratio C_{MIM}/Cdo and discontinuities in capacitance characteristic. To remove the discontinuities the dummy branches 192-194 are added to the first 3 LSB bits.

Operation is explained with FIGS. 15A and 15B, showing one of the LSB bits of the capacitance arrays 31 and 191. FIG. 15A shows the original situation on the left hand side, a subscript a is introduced referring to FIG. 15A. The MOST 9 uses Wdes=35 which is the desired value in the bit sequence needed for producing the desired capacitance ratio of Cdo1a with respect to MiM capacitor 2 having capacitance value C1a. On the right hand side in FIG. 15B subscript b is introduced for the dummy branch and the width of the MOST switch 199 has been increased to W=280, to reduce series resistance. In the previous table the actual width W is designated as Wact. The MiM capacitors 2, 195 and 222 with capacitances C1a, C1b and C11 all having the same value.

To be able to compensate for the too large capacitance in OFF state, the switches 32 (FIG. 15A), 203 and 219 (FIG. 15B) operate in tandem. A dummy MOST 231 having capacitance Cdo 11 in series with a MiM capacitor 222 with capacitance C11=C1b is added via the switch 219. The minimum and maximum capacitances delivered by circuits of FIGS. 15A and 15B will be

$$\frac{{C}_{a , MAX}}{{C}_{a , MIN}} = \frac{{C}_{1 a}}{\frac{{C}_{1 a} {C}_{do 1 a}}{{C}_{1 a} + {C}_{do 1 a}}}$$

$$\frac{{C}_{b , MAX}}{{C}_{b , MIN}} = \frac{{C}_{1 b} + \frac{{C}_{11} {C}_{do 11}}{{C}_{11} + {C}_{do 11}}}{\frac{{C}_{1 b} {C}_{do 1 b}}{{C}_{1 b} + {C}_{do 1 b}}}$$

Capacitance compensation comes at the penalty of a small, fixed parallel capacitance denoted as C₁ₚ present in ON and OFF state. For continuity of capacitance we need to fulfill

$$\frac{{C}_{b , MAX}}{{C}_{b , MIN}} = \frac{{C}_{1 p} + {C}_{a , MAX}}{{C}_{1 p} + {C}_{a , MIN}}$$

substituting Ca

$$\frac{{C}_{b , MAX}}{{C}_{b , MIN}} = \frac{{C}_{1 p} + {C}_{1 a}}{{C}_{1 p} + \frac{{C}_{1 a} {C}_{do 1 a}}{{C}_{1 a} + {C}_{do 1 a}}}$$

Solving for Cdo11 gives

$${C}_{do 11} = \frac{{C}_{MIM}^{2} ( {C}_{do 1 b} - {C}_{do 1 a} )}{{C}_{MIM}^{2} + 2 {C}_{do 1 a} {C}_{MIM} + {C}_{do 1 a} {C}_{do 1 b}}$$

where

C_{MiM}=C₁ₐ=C_{1b}=C₁₁

Positions of the dummy MOST switches 219, 220, 221 follow that of the array MOST switches 203, 204 and 205. Capacitance and loss resistance contributed by switching elements 219-221 form additional disturbing factor that has been left out of consideration. In summary there is found a considerable improvement of capacitor performance with implementation as in FIG. 14. Note that in order for the compensation of capacitance to be insensitive to process spread and temperature, the compensating capacitance needs to be composed of MiM and MOST capacitance in proper ratio in accordance with capacitance to be compensated. So e.g. we cannot compensate purely with Cdo leaving out Cmim or purely with MiM leaving out Cdo.

FIG. 16 is a graph XVII showing a linearized series resistance versus an input word using circuit FIG. 14. Graphs XVIII and XIX show dC/dW and capacitance versus the input word.

FIG. 17 is an embodiment of one array component 240 with a switched capacitor 241 and a dummy branch 242. A PMOST 243 is used to connect or disconnect the capacitance of dummy NMOST 244 to the output 26. When Vsw=Vcc the MOS transistors 243 and 245 are both in conducting state. The NMOST 244 drain DC voltage then is Vcc, in accordance with NMOST 245. The DC biasing reduces the n+ to P-well capacitance, refer to NMOST cross section as shown in FIG. 18. When Vsw=0V the MOS transistors 243 and 245 are in non-conducting state. Drain of MOST 245 is pulled to Vcc. Resistors 246 and 247 are forming a voltage divider and so drain of MOST 244 is pulled to approximately Vcc/2. The increased p+ to N-well reverse bias reduces capacitance contributed by MOST 243, refer to PMOST cross section as shown in FIG. 19.

FIG. 18 is a cross section of the NMOS transistors 244, 245. Drain 251 and source 252 are formed by n+ contacts 251, 252 in P-well area 253. The P-well 253 connects to the substrate 254.

FIG. 19 is a cross section of the PMOS transistor 243. Drain 256 and source 257 are formed by p+ contacts 256, 257 in N-well 258. The N-well 258 is isolated from substrate 259.

FIG. 20 shows a receiver 262 with a first capacitance array 263, a low noise amplifier 264, an inductor 265, a second capacitance array 266, two automatic gain controls 267 and 268, a mixer 269, a divider 270, a low-pass/polyphase filter 271, a received signal strength indicator 272, a tuning control 273, three automatic gain controls 274, 275 and 276, a crystal oscillator 277, a synthesiser 278 and a control interface 279. The receiver 262 comprises a loop antenna 280 tuned with a first capacitance array 263, a channel decoder 281 and a loop filter 282. The second capacitance array 266 is parallel the inductor 265 and put behind the low noise amplifier 264 and in front of the automatic gain control 267.

FIG. 21 shows an embodiment of an 8-bit array 301 of capacitors 302-309 switched by MOS transistors 310-317. The MOS transistors 310-317 receive their control signal via inputs 318-325. The array capacitors 302-309 are connected in parallel to output terminal 328. The transistors 310-317 are in series with the capacitors 302-309. The capacitor 302 is in series with transistor 310. The capacitor 303 is in series with transistor 311 and so on. The capacitors 302-309 are connected with a signal line 326 and the transistors 310-317 to an output line 327 which can be ground. The output line 327 is also designated as second signal line. Inputs 318-325 receive binary coded control signals b1-b8 forming an array input word. The input word controls the array MOS transistors 310-317. The array 301, between signal terminals 328 and 329, replaces a varactor diode with capacitance Cvar and a series resistance Rs.

FIG. 22 shows a schematic diagram of the equivalent circuit 331 for the array 301. Transistor 310 is modelled by a circuit comprising a switch 332, resistor 333 representing the MOST On-Resistance Ron1, a capacitor 335 in series with resistor 334 representing the parasitic Off-Capacitance Cp1 and parasitic series resistance Roff1, respectively. Like wise, transistor 311 is replaced by a circuit comprising a switch 336, a resistor 337 representing the MOST On-Resistance Ron2, a capacitor 339 in series with resistor 338 representing the parasitic Off-Capacitance Cp2 and parasitic series resistance Roff2 respectively. Transistor 317 is replaced by a circuit comprising a switch 344, a resistor 345 representing the MOST On-Resistance Ronmax, a capacitor 347 in series with resistor 346 representing the parasitic Off-Capacitance Cpmax and parasitic series resistance Roffmax respectively.

If one neglects the parasitic capacity of the MOS switches, the capacity of a branch comprising a switch and a capacitor is Cᵢ=2ⁱ⁻¹*ΔC, wherein ΔC is a step size capacity and i=1, 2, . . . , max. In reality, there is a parasitic capacity of the switches, which affects the dependence between the capacitance of the array as a function of tuning voltage. If the parasitic capacity is considered then jumps are observed in the plot of the capacitance as a function of tuning voltage.

To prevent these jumps, the capacitance of the switches is increased as shown in the following relation, wherein Cₚᵢ is the parasitic capacitance of the switch in OFF state.

$${C}_{i} = {2}^{i - 1} \cdot Δ C + \frac{{C}_{i} \cdot {Cp}_{i}}{{C}_{i} + {Cp}_{i}}$$

This gives

$${C}_{i} = \frac{1}{4} \cdot ( {2}^{i} \cdot Δ C + {2}^{\frac{i}{2}} \cdot \sqrt{Δ C} \cdot \sqrt{8 \cdot {Cp}_{i} + {2}^{i} \cdot Δ C} )$$

FIG. 23 shows the dependency XX between the capacitance and the tuning voltage. As it is expected, the capacitance is proportional versus the tuning range. Furthermore, the capacity maintains its monotonicity versus tuning voltage.

Unfortunately, the equivalent series resistance of the capacitor array depends on the tuning voltage, having a minimum value and a maximum value as shown in FIG. 24. In FIG. 24 it is represented an equivalent series resistance dependency versus the tuning voltage XXII. The series resistance of the array increases and decreases as function of the tuning voltage.

For constant bandwidth and voltage standing wave ratio, VSWR for short, as function of tuning, the equivalent series resistance should be constant. To lower the ratio between the maximum and minimum value, the switch sizes can be optimised.

FIG. 25 shows a graph XXII describing the dependency between the optimised equivalent series resistance versus the tuning voltage. The target of optimizing the switch size is to reduce the ratio between the maximum and minimum series resistance value.

Further improvement can be obtained by splitting each switch in parallel switches. By this method, when the switches are selectively deactivated i.e. they are in an OFF state, the equivalent resistance increases and reciprocally, when the switches are selectively activated i.e. they are in an ON state the equivalent resistance decreases.

FIG. 26 is depicts a graph XXIII showing the dependency of an equivalent series resistance versus the tuning voltage, the resistance being optimised by splitting switches in parallel. The capacitor-tuning curve is not affected, as the switch parasitic capacitor Cpᵢ does not change.

Still, process spread can cause jumps in the capacitance-tuning curve and influence the tuning range. When the capacitors in the array are smaller and/or switch parasitics larger, gaps will occur and not all capacitors values can be tuned to. If the parasitic capacitance increases, then the minimum tuned capacitor also increases. If the capacitors in the array are smaller, then the maximum tuned capacitor is reduced proportionally. The smallest tuned capacitor value is less affected. To prevent gaps in the tuning characteristic i.e. the dependency between the tuned capacity and the tuning voltage, overlap should be considered by calculating the capacitance of the capacitors in the array in the worst case i.e. when the parasitic capacitance has a maximum value Cpmax. After this, the value of the capacitors in the array should be multiplied by the ratio nominal capacitance/minimal capacitance array capacitor value, which is the worst case. Tuning range should be sufficient for the worst-case situation. In FIG. 27 a graph XXIV showing a continuously tuning capacitance over the tuning range is shown.

### REFERENCE LIST

1 array of capacitors 34 parallel resistor
2 capacitor 35 parallel capacitor
3 capacitor 36 switch
4 capacitor 370N-resistor
5 capacitor 38 parallel resistor
6 capacitor 39 parallel capacitor
7 capacitor 40 switch
8 capacitor 410N-resistor
9 MOS transistor 42 parallel resistor
10 MOS transistor 43 parallel capacitor
11 MOS transistor 44 switch
12 MOS transistor 450N-resistor
13 MOS transistor 46 parallel resistor
14 MOS transistor 47 parallel capacitor
15 MOS transistor 61 array
16 input 62 switch
17 input 63 switch
18 input 64 switch
19 input 65 switch
20 input 66 switch
21 input 67 switch
22 input 68 switch
23 signal line 69 active MOS transistor
24 signal line 70 active MOS transistor
25 input/output 71 active MOS transistor
26 input/output 72 active MOS transistor
31 equivalent circuit 73 active MOS transistor
32 switch 74 active MOS transistor
33 ON-resistor 75 active MOS transistor
34 parallel resistor
35 parallel capacitor
36 switch
37 ON-resistor
38 parallel resistor
39 parallel capacitor
40 switch
41 ON-resistor
42 parallel resistor
43 parallel capacitor
44 switch
45 ON-resistor
46 parallel resistor
47 parallel capacitor
61 array
62 switch
63 switch
64 switch
65 switch
66 switch
67 switch
68 switch
69 active MOS transistor
70 active MOS transistor
71 active MOS transistor
72 active MOS transistor
73 active MOS transistor
74 active MOS transistor
75 active MOS transistor passive MOS transistor 131 active MOS transistor passive MOS transistor 132 active MOS transistor passive MOS transistor 133 active MOS transistor passive MOS transistor 134 coder equivalent circuit 135 coder switch 141 array resistor 142 Pull-up-resistor resistor 143 Pull-up-resistor capacitor 144 Pull-up-resistor resistor 145 Pull-up-resistor capacitor 146 Pull-up-resistor switch 147 Pull-up-resistor resistor 148 Pull-up-resistor resistor 149 tap capacitor 150 tap resistor 151 tap capacitor 152 tap array of capacitors 153 tap switch 154 tap passive MOS transistor 155 tap active part 156 capacitor active MOS transistor 157 positive supply active MOS transistor 161 array coder 162 Pull-up-resistor array 163 Pull-up-resistor switch 164 Pull-up-resistor switch 165 Pull-up-resistor passive MOS transistor 166 Pull-up-resistor active part 167 Pull-up-resistor active MOS transistor 168 Pull-up-resistor active MOS transistor 169 transistor passive MOS transistor 170 transistor active part 171 transistor active MOS transistor 172 transistor transistor 212 resistor transistor 213 resistor transistor 214 resistor tap 215 capacitor tap 216 capacitor tap 217 capacitor tap 218 capacitor cap 219 switch tap 220 switch tap 221 switch resistor 222 capacitor positive supply 223 capacitor equivalent circuit 224 capacitor array 225 resistor dummy branch 226 resistor dummy branch 227 resistor dummy branch 228 capacitor capacitor 229 capacitor capacitor 230 capacitor capacitor 231 dummy MOST capacitor 232 dummy MOST MOST 233 dummy MOST MOST 240 array component MOST 241 switched capacitor MOST 242 dummy branch switch 243 PMOST switch 244 dummy NMOST switch 245 NMOST switch 248 resistor resistor 249 resistor resistor 251 drain resistor 252 source resistor 253 P-well area resistor 254 substrate 256 drain 310 MOS transistor 257 source 311 MOS transistor 258 N-well area 312 MOS transistor 259 substrat 313 MOS transistor 262 transceiver 314 MOS transistor 263 capacitor 315 MOS transistor 264 low noise amplifier 316 MOS transistor 265 inductor 317 MOS transistor 266 capacitance array 318 input 267 automatic gain control 319 input 268 automatic gain control 320 input 269 mixer 321 input 270 divider 322 input 271 a low-pass/polyphase filter 323 input 272 indicator 324 input 273 tuning control 325 input 274 automatic gain control 326 signal line 275 automatic gain control 327 signal line 276 automatic gain control 328 input/output 277 crystal oscillator 329 input 1 output 278 synthesiser 331 equivalent circuit 279 control interphase 332 switch 280 loop antenna 3330N-resistor channel decoder 334 parasitic resistor loop filter 335 parasitic capacitor 301 array of capacitors 336 switch capacitor 3370N-x esistor capacitor 338 parasitic resistor capacitor 339 parasitic capacitor capacitor 344 switch capacitor 3450N-resistor capacitor 346 parasitic resistor capacitor 347 parasitic capacitor capacitor 351 peak peak peak peak peak range range range range range overlap overlap overlap

1. An array of capacitors each having a capacitance, the array comprising:
MOS transistors for switching the array of capacitors,
a geometric property of each of the MOS transistors being proportional to the capacitance of the capacitor to which the MOS transistor is coupled.

2. A array as claimed in claim 1, wherein the geometric property is width.

3. An array of capacitors as claimed in claim 1, wherein the capacitances of the MOS transistors are binary weighted.

4. An array of capacitors as claimed in claim 1, the array further including a further MOS transistor coupled parallel to a MOS transistor both being coupled in series with one capacitor of the array.

5. Array of capacitors according to claim 4, wherein a gate terminal of the further MOS transistor coupled to a reference terminal.

6. Array of capacitors according to claim 4, wherein the parallel MOS transistors are controlled by a coder.

7. Array of capacitors according to claim 6, characterized in that the coder is controlled by Most Significant Bits of an input binary word.

8. Array of capacitors for being switched by MOS transistors as claimed in claim 1, the array further comprising a resistor coupled to a tap between the capacitor and the MOS transistor.

9. Array of capacitors according to claim 8, wherein the resistor is coupled to the tap via an additional MOS transistor

10. Array of capacitors according to claim 9, wherein the resistor is coupled to a signal line

11. Array of capacitors according to claim 8, wherein the resistors are binary weighted.

12. Array of capacitors array according to claim 10, wherein the signal line is coupled to a positive supply via resistor means

13. Array of capacitors as claimed in claim 1, wherein the MOS transistors are controlled by a binary word having a Least Significant Portion, the MOS transistors, which are controlled by the least Significant Portion comprising a relatively small resistance.

14. Array of capacitors according to claim 13, further comprising dummy branches coupled in parallel to the Least Significant Portion controlled MOS transistors and the capacitors switched by these MOS transistors

15. Array of capacitors according to claim 14, wherein the dummy branches comprise capacitors having the same capacitance as the capacitors included in the array of capacitors.

16. An array of capacitors as claimed in claim 1, wherein a value of a capacitance of any capacitor of the array comprises a weighted basic value and an additional value.

17. An array of capacitors according to claim 16, wherein the array further including a further MOS transistor coupled parallel to the MOS transistor, both being coupled in series with one capacitor the array.

18. Array of capacitors according to claim 17, wherein the parallel MOS transistors are controlled by a coder.

19. Array of capacitors according to claim 18, wherein the coder is controlled by Most Significant Bits of an input binary word.

20. Array of capacitors according to claim 1 wherein a further capacitor is coupled to two signal lines.

21. Array of capacitors according to claim 1, wherein the capacitors included in the array are Metal-Insulator-Metal capacitors.

22. Array of capacitors as claimed in claim 1, wherein the capacitances of the capacitors of the array are binary weighted.

23. Tunable filter comprising an array of capacitors according to claim 1.

24. TV tuner including a tunable array of capacitors as claimed in claim 1.

25. Receiver comprising an array of capacitors as claimed in claim 1.

26. Transceiver comprising an array of capacitors as claimed in claim 1.
